(19) United States
(12) Patent Application Publication
(10) Pub. No.: US 2015/0241215 A1
(43) Pub. Date: Aug. 27, 2015

(54) MICRO ELECTRO MECHANICAL SYSTEMS SENSOR

(71) Applicant: SAMSUNG ELECTRO-MECHANICS CO., LTD., Gyeonggi-Do (KR)

(72) Inventors: Jong Woon KIM, Gyeonggi-Do (KR); Seung Hun HAN, Gyeonggi-Do (KR); Sung Jun LEE, Gyeonggi-Do (KR); Sung Wook KIM, Gyeonggi-Do (KR); Chang Hyun LIM, Gyeonggi-Do (KR)

(73) Assignee: SAMSUNG ELECTRO-MECHANICS CO., LTD., Gyeonggi-Do (KR)

(21) Appl. No.: 14/602,031

(22) Filed: Jan. 21, 2015

(30) Foreign Application Priority Data
Feb. 27, 2014 (KR) 10-2014-0023387

(51) Int. Cl. G01C 19/5712; B81B 3/00

(52) U.S. Cl. CPC G01C 19/5712; B81B 3/0072; B81B 2201/0235

(57) ABSTRACT

Embodiments of the invention provide a MEMS sensor, including a mass body, a flexible beam coupled with the mass body, and a support part coupled with the flexible beam and floatably supporting the mass body. According to at least one embodiment, the flexible beam is provided with a sensing device configured to detect a physical amount depending on a displacement of the mass body, and a connection part between the flexible beam and the support part is provided with a reinforcement part to relax stress concentration in response to rigidity reinforcement.

### CROSS REFERENCE TO RELATED APPLICATION

This application claims the benefit of and priority under 35 U.S.C. §119 to Korean Patent Application No. KR 10-2014-0023387, entitled “MICRO ELECTRO MECHANICAL SYSTEMS SENSOR,” filed on Feb. 27, 2014, which is hereby incorporated by reference in its entirety into this application.

### BACKGROUND

1. Field of the Invention

The present invention relates to a micro electro mechanical systems (MEMS) sensor.

2. Description of the Related Art

Generally, an inertial sensor has been used, for example, in a car, aircraft, mobile communication terminals, toys, and requires a 3-axis acceleration and angular velocity sensor, which measures X-axis, Y-axis and Z-axis accelerations and angular velocities, and has been developed to have high performance and be miniaturized to detect a fine acceleration.

Among the inertial sensors, the acceleration sensor according to the conventional art includes technical features, which convert motions of a mass body and a flexible beam into electrical signals and as a type of the acceleration sensor, there are a piezoresistive type, which detects the motion of the mass body from a change in resistance of a piezoresistance element disposed in the flexible beam, and a capacitive type, which detects the motion of the mass body from a change in capacitance with a fixed electrode, as non-limiting examples.

Further, the piezoresistive type uses an element, which has a variable resistance value due to a stress, and for example, the resistance value is increased at a place at which a tensile stress is distributed and the resistance value is reduced at a place at which a compression stress is distributed.

Further, a piezoresistive accelerator sensor according to the conventional art, for example, U.S. Patent Publication No. 2006/0156818, has a stress concentrated on a mass body or a connection part between a fixed part and a flexible part, and therefore experiences problems, such as the reduction in sensitivity and the occurrence of impact damage.

### SUMMARY

Accordingly, embodiments of the invention have been made to provide a MEMS sensor, which may be damaged less in response to a reduction in stress concentration and maintain sensitivity to secure sensing reliability by forming a reinforcement part to correspond to a connection part between a flexible beam and a support part.

Furthermore, embodiments of the invention have been made to provide a MEMS sensor, which is configured of a first sensor unit including a piezoresistive accelerator sensor and a second sensor unit including a piezoelectric element and may be damaged less in response to a reduction in stress concentration on a mass body and a connection part between a flexible beam and a support part without separately performing an additional process and maintain sensitivity to secure sensing reliability by forming a piezoelectric material as a reinforcement part of the first sensor unit at the time of forming a device in the second sensor unit using the piezoelectric material.

According to at least one embodiment, there is provided a MEMS sensor, including a mass body, a flexible beam coupled with the mass body, and a support part coupled with the flexible beam and floatably supporting the mass body. According to at least one embodiment, the flexible beam is provided with a sensing device for detecting a physical amount depending on a displacement of the mass body and a connection part between the flexible beam and the support part is provided with a reinforcement part to relax stress concentrationin response to rigidity reinforcement.

According to at least one embodiment, the reinforcement part is formed to cover the connection part.

According to at least one embodiment, the reinforcement part is made of high-rigidity materials including at least one of metal and ceramic.

According to at least one embodiment, the reinforcement part has a predetermined thickness and an edge thereof is provided with a chamfer or a fillet.

According to at least one embodiment, the sensing device is formed to be adjacent to an end of the reinforcement part.

According to at least one other embodiment, there is provided a MEMS sensor, including a mass body, a flexible beam coupled with the mass body, and a support part coupled with the flexible beam and floatably supporting the mass body. According to at least one embodiment, the flexible beam is provided with a first sensing device and a second sensing device for detecting a physical amount depending on a displacement of the mass body, a connection part between the flexible beam and the support part is provided with a first reinforcement part to relax stress concentration in response to rigidity reinforcement, and a connection part between the flexible beam and the mass body is provided with a second reinforcement part to relax stress concentration in response to rigidity reinforcement.

According to at least one embodiment, the first reinforcement part and the second reinforcement part are each formed to cover the connection part.

According to at least one embodiment, the first reinforcement part and the second reinforcement part are made of high-rigidity materials including at least one of metal and ceramic.

According to at least one embodiment, the first reinforcement part and the second reinforcement part have a predetermined thickness and edges thereof are provided with a chamfer or a fillet.

According to at least one embodiment, the first sensing device is formed to be adjacent to an end of the first reinforcement part and the second sensing device is formed to be adjacent to an end of the second reinforcement part.

According to at least one other embodiment, there is provided a MEMS sensor, including a first sensor unit, which includes a mass body, a flexible beam coupled with the mass body, and a support part coupled with the flexible beam and floatably supporting the mass body. According to at least one embodiment, the flexible beam is provided with a sensing device for detecting a physical amount depending on a displacement of the mass body and a connection part between the flexible beam and the support part being provided with a reinforcement part to relax stress concentration in response to rigidity reinforcement; and a second sensor unit, which includes the mass body, the flexible beam coupled with the mass body, and the support part coupled with the flexible beam and floatably supporting the mass body, the flexible beam being provided with a sensing device for detecting the displacement of the mass body. According to at least one embodiment, the sensing device of the second sensor unit is formed of a piezoelectric material and the reinforcement part of the first sensor unit is made of the piezoelectric material.

According to at least one embodiment, the flexible beam of the first sensor unit is provided with a first sensing device and a second sensing device for detecting a physical amount depending on a displacement of the mass body, a connection part between the flexible beam of the first sensor unit and the support part are provided with a first reinforcement part to relax stress concentration in response to rigidity reinforcement, and a connection part between the flexible beam of the first sensor unit and the mass body is provided with a second reinforcement part to relax stress concentration in response to rigidity reinforcement.

According to at least one embodiment, the first reinforcement part and the second reinforcement part are each formed to cover the connection part.

According to at least one embodiment, the first reinforcement part and the second reinforcement part have predetermined thickness and edges thereof are provided with a chamfer or a fillet.

According to at least one embodiment, the first sensing device is formed to be adjacent to an end of the first reinforcement part and the second sensing device is formed to be adjacent to an end of the second reinforcement part.

According to at least one embodiment, the second sensor unit further includes a driving device for driving the mass body.

According to at least one embodiment, the driving device is formed of a piezoelectric material.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a schematic perspective view of a MEMS sensor according to an embodiment of the invention.

FIG. 2 is a cross-sectional view taken along the line A-A′ of the MEMS sensor illustrated in FIG. 1 according to an embodiment of the invention.

FIG. 3 is a schematic perspective view of a MEMS sensor according to another embodiment of the invention.

FIG. 4 is a schematic cross-sectional view taken along the line B-B of the MEMS sensor illustrated in FIG. 2 according to another embodiment of the invention.

FIG. 5 is a schematic perspective view of a MEMS sensor according to another embodiment of the invention.

FIG. 6 is a perspective view schematically illustrating a second sensor unit according to another embodiment of the MEMS sensor illustrated in FIG. 5.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

Hereinafter, various embodiments of the present invention will be described in detail with reference to the accompanying drawings.

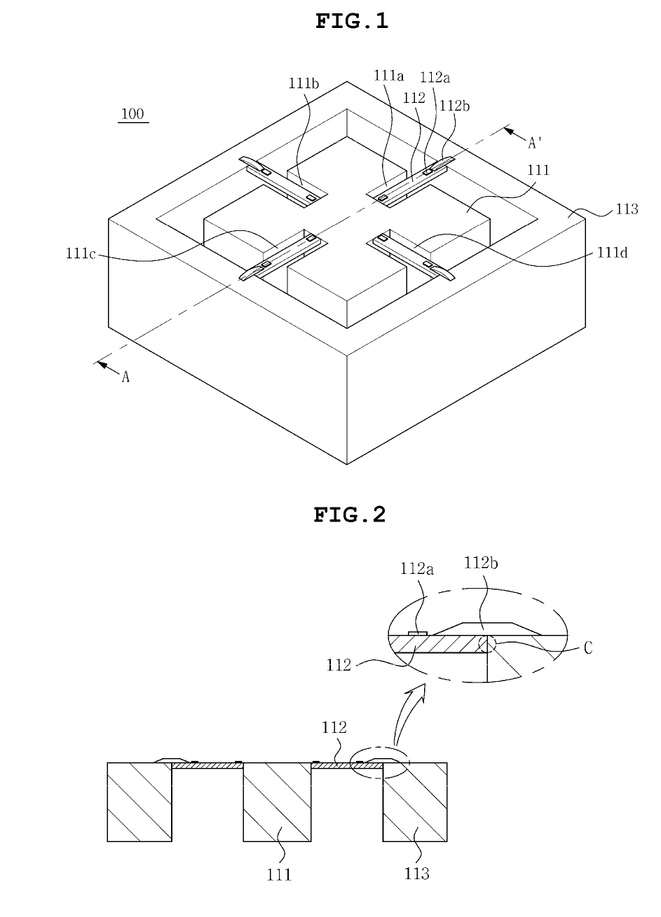

FIG. 1 is a schematic perspective view of a MEMS sensor according to an embodiment of the invention, and FIG. 2 is a cross-sectional view taken along the line A-A′ of the MEMS sensor illustrated in FIG. 1 according to an embodiment of the invention.

As illustrated, a MEMS sensor 100 includes a mass body 111, a flexible beam 112, and a support part 113 and is implemented as an accelerator sensor.

Further, the flexible beam 112 is provided with a sensing device 112a, which detects a physical amount depending on a displacement of the mass body 111 and a connection part between the flexible beam 112 and the support part 113 is provided with a reinforcement part 112b to relax stress concentration in response to rigidity reinforcement.

Therefore, the MEMS sensor 100, according to at least one embodiment, is less damaged in response to the reduction in stress concentration and maintains sensitivity to secure reliability.

To this end, detailed technical components, organic coupling therebetween, acting effect will be described in more detail.

In more detail, the mass body 111, according to at least one embodiment, is displaceably coupled with the flexible beam 112 and is displaced by, for example, an inertial force, an external force, a Coriolis force, a driving force, as non-limiting examples.

According to at least one embodiment, the mass body 111 is illustrated as being formed in a square pillar shape, but is not limited thereto, and therefore may be formed in all the shapes known in the art, such as a cylinder.

According to at least one embodiment, the mass body 111 is provided with four groove parts 111a, 111b, 111c, and 111d at equidistance, so that the flexible beams 112 are connected to the mass body 111 in all directions and are formed in a rectangular parallelepiped shape.

Thus, in order for a central portion of the mass body 111 to be displaceably fixed by the flexible beam 112, the four groove parts 111a, 111b, 111c, and 111d are formed to extend toward the central portion of the mass body 111 from an outer side thereof and the central portion of the mass body 111 is coupled with each of the four flexible beams 112 in all directions.

Next, the flexible beam 112 is formed in a plate shape and is configured of a flexible substrate, such as a membrane and a beam, which have elasticity to allow the mass body 111 to be displaced. Further, ends of the flexible beams 112 are connected to the central portion of the mass body 111 through the groove parts 111a, 111b, 111c, and 111d of the mass body 111 and the other ends thereof are connected to the support part 113.

According to at least one embodiment, one surface of the flexible beam 112 is provided with the sensing device 112a for detecting a displacement of the mass body and the sensing device 112a is variously configured of, for example, a piezoelectric material, and a piezoresistive material, as non-limiting examples.

Further, as described above, the flexible beam 112 is provided with a reinforcement part 112b to relax stress concentration in response to rigidity reinforcement to correspond to a connection part C with the support part 113. In more detail, the reinforcement part 112b is formed on the flexible beam 112 and the support part 113 to cover the connection part C between the flexible beam 112 and the support part 113.

Further, the reinforcement part 112b is formed on one surface of the flexible beam 112 and the support part 113 and is disposed to correspond to the connection part C.

According to at least one embodiment, the reinforcement part 112b is made of high-rigidity materials including at least one of metal and ceramic.

According to at least one embodiment, the reinforcement part 112b has a predetermined thickness and an edge thereof is provided with a chamfer or a fillet. Further, the chamber or the fillet is formed by an isotropic or anisotropic etching process meeting the high-rigidity material.

According to at least one embodiment, the sensing device 112a of the flexible beam 112 is formed to be adjacent to the end of the reinforcement part 112b. Further, the sensing device 112a of the flexible beam 112 is formed to be adjacent to the end of the reinforcement part 112b, which is adjacent to the mass body.

Next, the support part 113 is coupled with the flexible beam 112, which is coupled with the mass body 111 to floatably support the mass body 111, and the support part 113 is formed in a hollow shape, so that the mass body 111 is displaced, thereby securing a space in which the mass body 111 is displaced.

According to at least one embodiment, as described above, as the reinforcement part 112b is formed to cover the connection part C with the flexible beam 112, one surface of the support part 113, which faces the connection part C is provided with the reinforcement part 112b.

By the configuration, the MEMS sensor 100, according to at least one embodiment, is less damaged in response to the reduction in stress concentration and maintains sensitivity to secure the sensing reliability by forming the reinforcement part to correspond to the connection part C between the flexible beam 112 and the support part 113.

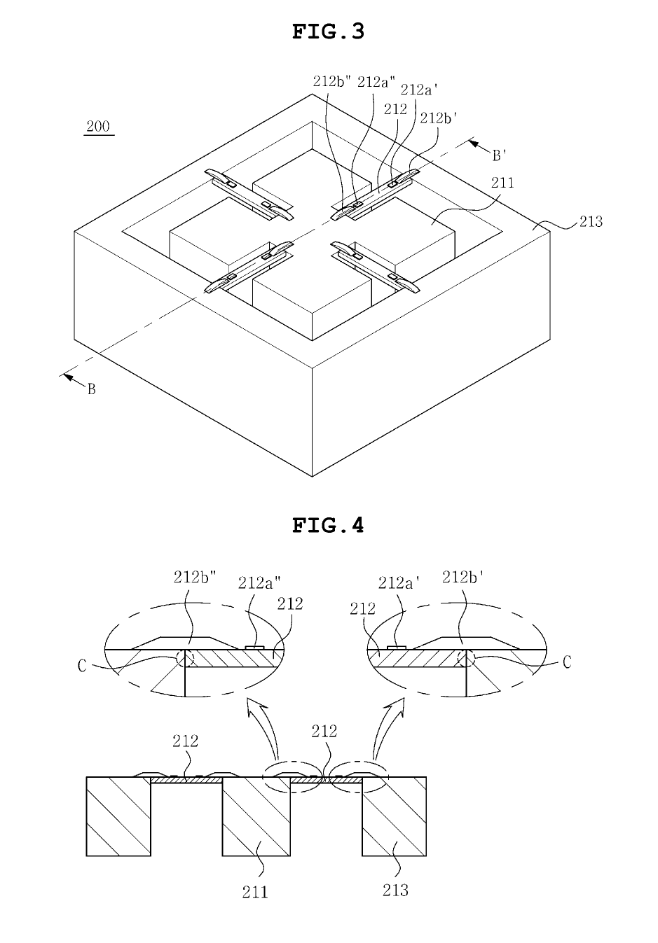

FIG. 3 is a schematic perspective view of a MEMS sensor according to another embodiment of the invention, and FIG. 4 is a schematic cross-sectional view taken along the line B-B of the MEMS sensor illustrated in FIG. 3 according to another embodiment of the invention. As illustrated, a MEMS sensor 200 is further provided with a reinforcement part as compared with the MEMS sensor 100 according to the embodiment illustrated in FIG. 1.

In more detail, the MEMS sensor 200 includes a mass body 211, a flexible beam 212, and a support part 213 and is implemented as an accelerator sensor.

According to at least one embodiment, the flexible beam 212 is provided with a first sensing device 212a′ and a second sensing device 212a″ for detecting a physical amount depending on a displacement of the mass body, a connection part between the flexible beam 212 and the support part 213 is provided with the first reinforcement part 212b′ to relax stress concentration in response to rigidity reinforcement, and a connection part between the flexible beam 212 and the mass body 211 is provided with a second reinforcement part 212b″ to relax stress concentration in response to the rigidity reinforcement.

Thus, the first reinforcement part 212b′ is formed on one surface of the flexible beam 212 and the support part 213 to cover the connection part C between the flexible beam 212 and the support part 213 and the second reinforcement part 212b″ is formed on one surface of the flexible beam 212 and the mass body 211 to cover the connection part C between the flexible beam 212 and the mass body 211.

According to at least one embodiment, the first reinforcement part 212b′ and the second reinforcement part 212b″ are made of high-rigidity materials, such as metal and ceramic.

According to at least one embodiment, the first reinforcement part 212b′ and the second reinforcement part 212b″ have a predetermined thickness and edges thereof are provided with a chamfer or a fillet. Further, the chamber or the fillet is formed by an isotropic or anisotropic etching process meeting the high-rigidity material.

According to at least one embodiment, the first sensing device 212a′ of the flexible beam 212 is formed to be adjacent to an end of the first reinforcement part 212b′, which is adjacent to the mass body 211. Further, the second sensing device 212a″ is formed to be adjacent to the end of the second reinforcement part 212b″, which is adjacent to the support part 213.

Further, a detailed configuration of the MEMS sensor 200 according to at least another embodiment is the same as the technical configuration corresponding to the MEMS sensor 100 described with reference to FIG. 1, and therefore the description of the detailed technical configuration thereof will be omitted.

By the configuration, the MEMS sensor 200 according to at least another embodiment is less damaged in response to the reduction in stress concentration on the mass body and the connection part between the flexible beam and the support part and maintains the sensitivity to secure the sensing reliability by forming the first reinforcement part 212b′ to be opposite to the connection part C between the flexible beam 212 and the support part 213 and forming the second reinforcement part 212b″ to be opposite to the connection part C between the flexible beam 212 and the mass body 211.

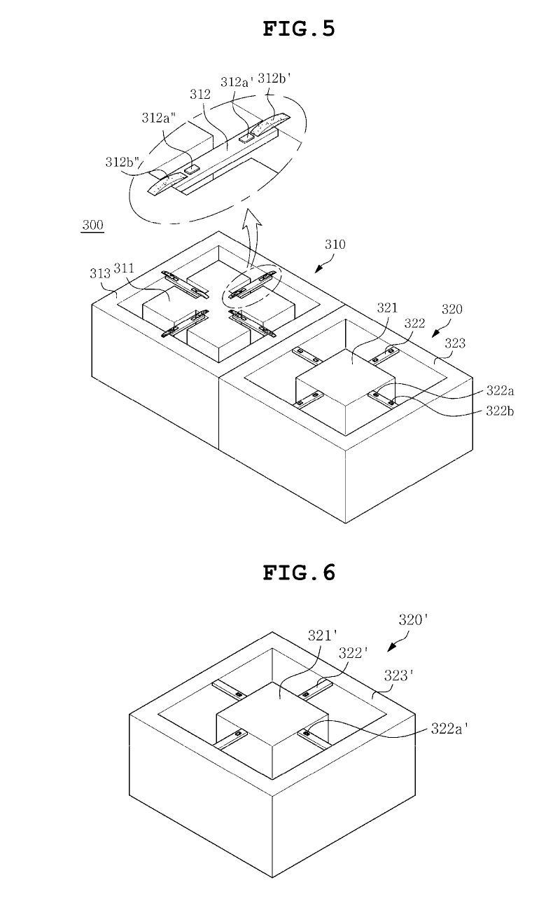

FIG. 5 is a schematic perspective view of a MEMS sensor according to another embodiment of the invention. As illustrated in FIG. 5, the MEMS sensor 300 includes a first sensor unit 310 and a second sensor unit 320, in which the first sensor unit 310 is configured of the accelerator sensor and the second sensor unit 320 is configured of an angular velocity sensor, a pressure sensor, and an accelerator sensor, which has a piezoelectric element. Further, FIG. 5 illustrates, by way of example, that the second sensor unit 320 is implemented as the angular velocity sensor having the piezoelectric element.

In more detail, the first sensor unit 310 of the MEMS sensor 300 is the same as the MEMS sensor 200 according to the embodiment of the invention illustrated in FIG. 3. Thus, the first sensor unit 310 includes a mass body 311, a flexible beam 312, and a support part 313, and the flexible beam 312 is provided with a first sensing device 312a′ and a second sensing device 312a″ for detecting a physical amount depending on a displacement of the mass body 311, the connection part between the flexible beam 312 and the support part 313 is provided with a first reinforcement part 312b′ to relax stress concentration in response to rigidity reinforcement, and the connection part between the flexible beam 312 and the mass body 311 is provided with the second reinforcement part 312b″ to relax stress concentration in response to the rigidity reinforcement.

Further, a detailed configuration of the first sensor unit 310 of the MEMS sensor 300 according to another embodiment of the invention is the same as the technical configuration corresponding to the MEMS sensor 200 described with reference to FIG. 3, and therefore the description of the detailed technical configuration thereof will be omitted.

Next, the second sensor unit 320 of the MEMS sensor 300 is implemented as an angular sensor. To this end, the second sensor unit 320 includes a mass body 321, a flexible beam 322, and a support part 323 and includes a driving device 322b and a sensing device 322a.

In more detail, the mass body 321 is displaceably coupled with the flexible beam 322 and is displaced by, for example, an inertial force, an external force, a Coriolis force, and a driving force, as non-limiting examples.

According to at least one embodiment, the flexible beam 322 is formed in a plate shape and is configured of a flexible substrate, such as a membrane and a beam, which have elasticity to allow the mass body 321 to be displaced.

According to at least one embodiment, one surface of the flexible beam 322 is provided with the sensing device 322a for detecting the displacement of the mass body and the driving device 322b for driving the mass body. Further, the sensing device 322a and the driving device 322b are formed of a piezoelectric material.

According to at least one embodiment, in a process of forming the sensing device 322a and the driving device 322b with the piezoelectric material, the first reinforcement part 312b′ and the second reinforcement part 312b″ of the first sensor part 310 are formed of a piezoelectric material.

Thus, the first reinforcement part 312b′ is formed on one surface of the flexible part 312 and the support part 313 to cover the connection part between the flexible beam 312 and the support part 313 and the second reinforcement part 312b″ is formed on one surface of the flexible beam 312 and the mass body 311 to cover the connection part between the flexible beam 312 and the mass body 311.

According to at least one embodiment, the first reinforcement part 312b′ and the second reinforcement part 312b″ have a predetermined thickness and edges thereof are provided with a chamfer or a fillet.

According to at least one embodiment, the first sensing device 312a′ of the flexible beam 312 is formed to be adjacent to an end of the first reinforcement part 312b′, which is adjacent to the mass body 311.

According to at least one embodiment, the second sensing device 312a″ is formed to be adjacent to the end of the second reinforcement part 312b″, which is adjacent to the support part 313.

By the above configuration, the MEMS sensor 300 according to at least one embodiment is implemented as a composite sensor in one chip and is damaged less in response to the reduction in stress concentration on the mass body and the connection part between the flexible beam and the support part without separately performing the additional process and maintains the sensitivity to secure the sensing reliability by forming the piezoelectric material as the reinforcement part of the first sensor unit at the time of forming the device in the second sensor unit using the piezoelectric material.

Meanwhile, as illustrated in FIG. 6, when the second sensor unit 320′ is implemented as the accelerator sensor or the pressure sensor, the second sensor unit 320′ is implemented without including the driving device. Thus, the second sensor unit 320′ includes a mass body 321′, a flexible beam 322′, and a support part 323′, in which the flexible beam 322′ is provided with a sensing device 322a′.

According to various embodiments of the invention, it is possible to obtain the MEMS sensor, which is reduced less in response to the reduction in stress concentration and maintains the sensitivity to secure the sensing reliability by forming the reinforcement part to correspond to the connection part between the flexible beam and the support part.

It is possible to obtain the MEMS sensor, which is configured of the first sensor unit including the piezoresistive accelerator sensor and the second sensor unit including the piezoelectric element and is damaged less in response to the reduction in stress concentration on the mass body and the connection part between the flexible beam and the support part without separately performing the additional process and keep the sensitivity to secure the sensing reliability by forming the piezoelectric material as the reinforcement part of the first sensor unit at the time of forming the device in the second sensor unit using the piezoelectric material.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A micro electro mechanical systems sensor, comprising:
a mass body;
a flexible beam coupled with the mass body; and
a support part coupled with the flexible beam and floatably supporting the mass body,
wherein the flexible beam is provided with a sensing device configured to detect a physical amount depending on a displacement of the mass body, and a connection part between the flexible beam and the support part is provided with a reinforcement part to relax stress concentration in response to rigidity reinforcement.

2. The micro electro mechanical systems sensor as set forth in claim 1, wherein the reinforcement part is formed to cover the connection part.

3. The micro electro mechanical systems sensor as set forth in claim 1, wherein the reinforcement part is made of high-rigidity materials including at least one of metal and ceramic.

4. The micro electro mechanical systems sensor as set forth in claim 1, wherein the reinforcement part has a predetermined thickness and an edge thereof is provided with a chamfer or a fillet.

5. The micro electro mechanical systems sensor as set forth in claim 1, wherein the sensing device is formed to be adjacent to an end of the reinforcement part.

6. A micro electro mechanical systems sensor, comprising:
a mass body;
a flexible beam coupled with the mass body; and
a support part coupled with the flexible beam and floatably supporting the mass body,
wherein the flexible beam is provided with a first sensing device and a second sensing device configured to detect a physical amount depending on a displacement of the mass body, a connection part between the flexible beam and the support part is provided with a first reinforcement part to relax stress concentration in response to rigidity reinforcement, and a connection part between the flexible beam and the mass body is provided with a second reinforcement part to relax stress concentration in response to rigidity reinforcement.

7. The micro electro mechanical systems sensor as set forth in claim 6, wherein the first reinforcement part and the second reinforcement part are each formed to cover the connection part.

8. The micro electro mechanical systems sensor as set forth in claim 6, wherein the first reinforcement part and the second reinforcement part are made of high-rigidity materials including at least one of metal and ceramic.

9. The micro electro mechanical systems sensor as set forth in claim 6, wherein the first reinforcement part and the second reinforcement part have a predetermined thickness and edges thereof are provided with a chamfer or a fillet.

10. The micro electro mechanical systems sensor as set forth in claim 6, wherein the first sensing device is formed to be adjacent to an end of the first reinforcement part and the second sensing device is formed to be adjacent to an end of the second reinforcement part.

11. A micro electro mechanical systems sensor, comprising:
a first sensor unit comprising a mass body, a flexible beam coupled with the mass body, and a support part coupled with the flexible beam and floatably supporting the mass body, wherein the flexible beam is provided with a sensing device for detecting a physical amount depending on a displacement of the mass body and a connection part between the flexible beam and the support part is provided with a reinforcement part to relax stress concentration in response to rigidity reinforcement; and
a second sensor unit comprising the mass body, the flexible beam coupled with the mass body, and the support part coupled with the flexible beam and floatably supporting the mass body, wherein the flexible beam is provided with a sensing device configured to detect the displacement of the mass body, wherein the sensing device of the second sensor unit is formed of a piezoelectric material and the reinforcement part of the first sensor unit is formed of the piezoelectric material.

12. The micro electro mechanical systems sensor as set forth in claim 11, wherein the flexible beam of the first sensor unit is provided with a first sensing device and a second sensing device configured to detect a physical amount depending on a displacement of the mass body, a connection part between the flexible beam of the first sensor unit and the support part is provided with a first reinforcement part to relax stress concentration in response to rigidity reinforcement, and a connection part between the flexible beam of the first sensor unit and the mass body is provided with a second reinforcement part to relax stress concentration in response to rigidity reinforcement.

13. The micro electro mechanical systems sensor as set forth in claim 12, wherein the first reinforcement part and the second reinforcement part are each formed to cover the connection part.

14. The micro electro mechanical systems sensor as set forth in claim 12, wherein the first reinforcement part and the second reinforcement part have a predetermined thickness and edges thereof are provided with a chamfer or a fillet.

15. The micro electro mechanical systems sensor as set forth in claim 12, wherein the first sensing device is formed to be adjacent to an end of the first reinforcement part and the second sensing device is formed to be adjacent to an end of the second reinforcement part.

16. The micro electro mechanical systems sensor as set forth in claim 12, wherein the second sensor unit further comprises a driving device for driving the mass body.

17. The micro electro mechanical systems sensor as set forth in claim 16, wherein the driving device is formed of a piezoelectric material.
